(19) United States
(12) Patent Application Publication
(10) Pub. No.: US 2020/0109486 A1
(43) Pub. Date: Apr. 9, 2020

(54) PLATING DEVICE FOR PRINTED INTERCONNECT BOARDS AND METAL JIG

(71) Applicants: SUMITOMO ELECTRIC INDUSTRIES, LTD., Osaka (JP); SUMITOMO ELECTRIC PRINTED CIRCUITS, INC., Shiga (JP)

(72) Inventors: Junichi MOTOMURA, Osaka (JP); Koji NITTA, Osaka (JP); Shoichiro SAKAI, Osaka (JP); Masahiro MATSUMOTO, Osaka (JP); Masahiro ITOH, Shiga (JP)

(21) Appl. No.: 16/620,981

(22) PCT Filed: Mar. 19, 2018
(86) PCT No.: PCT/JP2018/010724

§ 371 Date: Dec. 10, 2019

(30) Foreign Application Priority Data
Aug. 16, 2017 (JP) 2017-157277

(51) Int. Cl. C25D 17/08; C25D 7/00; H05K 3/18

(52) U.S. Cl. CPC C25D 17/08; C25D 7/00; H05K 2203/1545; H05K 2203/0723; H05K 2203/1518; H05K 3/18

(57) ABSTRACT

A plating device for printed interconnect boards includes: a plating bath configured to store a plating solution; a plurality of metal jigs; an anode disposed to face the base boards for printed interconnect boards; and a mechanism configured to apply a voltage to the anode and to the base boards for printed interconnect boards, wherein the plurality of metal jigs include insulating shielding plates at areas facing the anode and include, on sides of the base boards for printed interconnect boards and between the base boards for printed interconnect boards and the shielding plates, exposed surfaces that are orthogonal to the base boards for printed interconnect boards.

### TECHNICAL FIELD

The present invention relates to a plating device for printed interconnect boards and a metal jig.

The present application is based on and claims priority to Japanese Patent Application No. 2017-157277, filed on Aug. 16, 2017, the entire contents of the Japanese Patent Application are hereby incorporated herein by reference.

### BACKGROUND ART

In accordance with reduction of sizes of electronic devices and the like, interconnect patterns of printed interconnect boards used in electronic devices and the like have gradually become smaller. To base boards for printed interconnect boards before interconnect patterns are formed, plating for forming interconnect patterns is applied.

Conventionally, as a method of plating base boards for printed interconnect boards, an electrolytic plating method of a vertical continuous transferring type is known by which electrolytic plating is performed while causing a plurality of base boards for printed interconnect boards to be vertically orientated and continuously transferring these oriented base boards for printed interconnect boards in a plating bath (Patent Document 1).

Although the electrolytic plating method of Patent Document 1 is effective for plating a large number of base boards for printed interconnect boards at high speed, in order to continuously transfer a plurality of base boards for printed interconnect boards in a plating bath, jigs are required to hold the plurality of base boards for printed interconnect boards. As jigs for electrolytic plating, metal jigs such as stainless steel or copper are generally used because it is required to flow an electric current from a power supply to base boards for printed interconnect boards.

On the other hand, a metal jig is proposed in which a portion of a surface is covered with an insulating material (Patent Document 2). According to the metal jig of Patent Document 2, a partial insulation part is provided on the surface so as to be continuous from a surface position of base boards for printed interconnect boards, and the plating thickness can be made uniform by adjusting the current concentration with respect to the metal jig by the degree of partial insulation.

### PRIOR ART DOCUMENT

### Patent Document

[Patent Document 1] Japanese Laid-open Patent Publication No. 2009-41070

[Patent Document 2] Japanese Laid-open Patent Publication No. 2003-253496

### SUMMARY OF THE INVENTION

According to one aspect of the present invention, a plating device for printed interconnect boards includes: a plating bath configured to store a plating solution; a plurality of metal jigs that are immersed in the plating solution and disposed on pairs of side edge portions of a plurality of base boards for printed interconnect boards that constitute a cathode to fix the base boards for printed interconnect boards such that the side edge portions are parallel; an anode that is immersed in the plating solution and disposed to face the base boards for printed interconnect boards; and a mechanism configured to apply a voltage to the anode and to the base boards for printed interconnect boards. In the plating device for printed interconnect boards, the plurality of metal jigs include insulating shielding plates at areas facing the anode and include, on sides of the base boards for printed interconnect boards and between the base boards for printed interconnect boards and the shielding plates, exposed surfaces that are orthogonal to the base boards for printed interconnect boards.

According to another aspect of the present invention, a metal jig is to be used in a plating device for printed interconnect boards that includes: a plating bath configured to store a plating solution; a plurality of metal jigs that are immersed in the plating solution and disposed on pairs of side edge portions of a plurality of base boards for printed interconnect boards that constitute a cathode to fix the base boards for printed interconnect boards such that the side edge portions are parallel; an anode that is immersed in the plating solution and disposed to face the base boards for printed interconnect boards; and a mechanism configured to apply a voltage to the anode and to the base boards for printed interconnect boards. The metal jig includes insulating shielding plates at areas facing the anode and includes, on sides of one of the base boards for printed interconnect boards and between the one of the base boards for printed interconnect boards and the shielding plates, exposed surfaces that are orthogonal to the one of the base boards for printed interconnect boards.

### BRIEF DESCRIPTION OF THE DRAWINGS

FIG. 1 is a schematic plan view of a plating device for printed interconnect boards according to an embodiment of the present invention;

FIG. 2 is a schematic cross-sectional view of A-A of FIG. 1;

FIG. 3 is a schematic front view illustrating a state of transferring base boards for printed interconnect boards in the plating device for printed interconnect boards of FIG. 1;

FIG. 4 is a schematic horizontal cross-sectional view excluding a plating bath 2 in B-B of FIG. 2;

FIG. 5A is a schematic horizontal cross-sectional view hypothetically illustrating a flow of electric current in a case of using metal jigs having shielding plates on surfaces facing an anode;

FIG. 5B is a schematic horizontal cross-sectional view hypothetically illustrating a flow of electric current in a case of using metal jigs without shielding plates; and

FIG. 5C is a schematic horizontal cross-sectional view hypothetically illustrating a flow of electric current in a case of using metal jigs having shielding plates on surfaces facing an anode and side surfaces on the sides of base boards for printed interconnect boards.

### EMBODIMENT FOR CARRYING OUT THE INVENTION

### Problem to Be Solved by the Present Disclosure

When a metal jig is used as a jig for electrolytic plating, an electric current concentrates on a surface of the metal jig having good electrical conductivity and thereby a large amount of plating grows on the surface. Also, a plating thickness of a base board for a printed interconnect board near the metal jig becomes thinner than a plating thickness at a surface of the base board for a printed interconnect board away from the metal jig. As a result, a problem occurs that a plating thickness applied to base boards for printed interconnect boards is not uniform over the entire surface of the base boards for printed interconnect boards.

On the other hand, as in metal jigs of Patent Document 2, when partially insulating portions are provided on the surfaces of metal jigs so as to be in continuous from surface positions of base boards for printed interconnect boards, an electric current concentrates on the surfaces of the base boards for printed interconnect boards near the metal jigs by prevention of the electric current toward the metal jigs at the partially insulating portions, and the plating thickness on the surfaces of the base boards for printed interconnect boards near the metal jigs becomes thicker than the plating thickness on the surfaces of the base boards for printed interconnect boards away from the metal jigs. Therefore, even in a case where a metal jig of Patent Document 2 is used, a problem occurs that a plating thickness applied to base boards for printed interconnect boards is not uniform over the entire surface of the base boards for printed interconnect boards.

Therefore, an object is to provide a plating device for printed wiring boards and a metal jig that can make a plating thickness distribution uniform.

### Effect of the Present Disclosure

A plating device for printed wiring boards and a metal jig according to the present disclosure can make a plating thickness distribution uniform.

### Description of Embodiment of the Present Disclosure

First, aspects of the present invention will be listed and described.

According to one aspect of the present invention, a plating device for printed interconnect boards includes: a plating bath configured to store a plating solution; a plurality of metal jigs that are immersed in the plating solution and disposed on pairs of side edge portions of a plurality of base boards for printed interconnect boards that constitute a cathode to fix the base boards for printed interconnect boards such that the side edge portions are parallel; an anode that is immersed in the plating solution and disposed to face the base boards for printed interconnect boards; and a mechanism configured to apply a voltage to the anode and to the base boards for printed interconnect boards. In the plating device for printed interconnect boards, the plurality of metal jigs include insulating shielding plates at areas facing the anode and include, on sides of the base boards for printed interconnect boards and between the base boards for printed interconnect boards and the shielding plates, exposed surfaces that are orthogonal to the base boards for printed interconnect boards.

The plating device for printed interconnect boards includes the plurality of metal jigs that are disposed on the pairs of side edge portions of the base boards for printed interconnect boards that constitute a cathode, and these metal jigs fix the base boards for printed interconnect boards such that the side edge portions are parallel. Therefore, it is possible to continuously plate the plurality of base boards for printed interconnect boards. Because the plurality of metal jigs include the insulating shielding plates at the areas facing the anode, a flow of an electric current to the areas is suppressed. On the other hand, because the plurality of metal jigs include, on sides of the base boards for printed interconnect boards and between the base boards for printed interconnect boards and the shielding plates, the exposed surfaces that are orthogonal to the base boards for printed interconnect boards, a flow of an electric current to the exposed surfaces is permitted. Because the plurality of metal jigs of the plating device for printed interconnect boards include the shielding plates and the exposed surfaces described above, it is possible to adjust an amount of electric current flowing to the surfaces of the base boards for printed interconnect boards near the metal jigs in a balanced manner. For this reason, the plating device for printed interconnect boards can make the plating thickness distribution on the surfaces of the base boards for printed interconnect boards uniform. Here, “the side edge portions are parallel” means that the side edge portions are arranged on a straight line when the base boards for printed interconnect boards are viewed in a direction that is parallel with the planar direction of the base boards for printed interconnect boards and normal to the transferring direction of the base boards for printed interconnect boards.

It is preferable that a plating thickness distribution is controlled based on an average width of the exposed surfaces between the base boards for printed interconnect boards and the shielding plates and an average distance between the exposed surfaces of the plurality of metal jigs that are present between the base boards for printed interconnect boards next to each other. The inventors of the present invention have found that, by properly adjusting the average width of the exposed surfaces and the average distance between the exposed surfaces, the plating thickness on the surfaces of the base boards for printed interconnect boards near the metal jigs can be controlled. Thus, the plating device for printed interconnect boards can control the plating thickness distribution over the entire surfaces of the base boars for printed interconnect boards to be uniform by properly adjusting the average width and the average distance described above.

According to another aspect of the present invention, a metal jig is to be used in a plating device for printed interconnect boards that includes: a plating bath configured to store a plating solution; a plurality of metal jigs that are immersed in the plating solution and disposed on pairs of side edge portions of a plurality of base boards for printed interconnect boards that constitute a cathode to fix the base boards for printed interconnect boards such that the side edge portions are parallel; an anode that is immersed in the plating solution and disposed to face the base boards for printed interconnect boards; and a mechanism configured to apply a voltage to the anode and to the base boards for printed interconnect boards. The metal jig includes insulating shielding plates at areas facing the anode and includes, on sides of one of the base boards for printed interconnect boards and between the one of the base boards for printed interconnect boards and the shielding plates, exposed surfaces that are orthogonal to the one of the base boards for printed interconnect boards.

Because the metal jig includes the insulating shielding plates at the areas facing the anode, a flow of an electric current to the areas is suppressed. On the other hand, because the metal jigs includes, sides of one of the base boards for printed interconnect boards and between the one of the base boards for printed interconnect boards and the shielding plates, exposed surfaces that are orthogonal to the one of the base boards for printed interconnect boards, a flow of an electric current to the exposed surfaces is permitted. Because the metal jig includes the shielding plates and the exposed surfaces, when the base boards for printed interconnect boards are plated by the plating device for printed interconnect boards, it is possible to adjust an amount of electric current flowing to the surfaces of the base boards for printed interconnect boards near the metal jigs in a balanced manner. Therefore, according to the metal jig, it is possible to make the plating thickness distribution on the surfaces of the base boards for printed interconnect boards uniform.

### Details of Embodiment of the Present Invention

In the following, a plating device for printed interconnect boards and metals jigs according to an embodiment of the present invention will be described with reference to the drawings.

### Plating Device for Printed Interconnect Boards

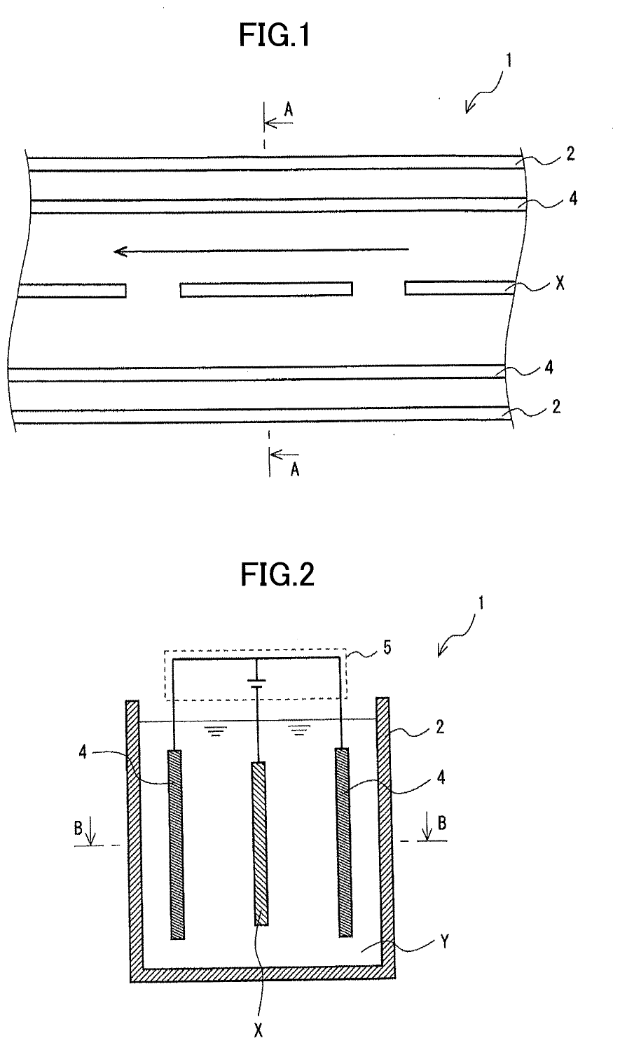

As in FIG. 1 to FIG. 4, a plating device 1 for printed interconnect boards includes: a plating bath 2 that stores a plating solution Y; a plurality of metal jigs 3 that are immersed in the plating solution Y and disposed on pairs of side edge portions Xa of a plurality of base boards X for printed interconnect boards that constitute a cathode to fix the base boards X for printed interconnect boards such that the side edge portions Xa are parallel; anodes 4 that are immersed in the plating solution Y and disposed to face the base boards X for printed interconnect boards; and a mechanism (voltage applying mechanism 5) configured to apply a voltage to the anodes 4 and to the base boards X for printed interconnect boards. Also, the plurality of metal jigs 3 includes insulating shielding plates 6 at areas (facing surfaces 3a) facing the anodes 4 and include, on sides of the base boards X for printed interconnect boards and between the base boards X for printed interconnect boards and the shielding plates 6, exposed surfaces 3b that are orthogonal to the base boards X for printed interconnect boards. In the plating device 1 for printed interconnect boards, the plating thickness distribution is controlled based on an average width t of the exposed surfaces 3b between the base boards X for printed interconnect boards and the shielding plates 6 and an average distance a between the exposed surfaces 6 of the plurality of metal jigs 3 that are present between the base boards X for printed interconnect boards next to each other.

The base boards X for printed interconnect boards, which are used in the plating device 1 for printed interconnect boards, are base boards for rectangular flexible printed interconnect boards each of which includes an insulating base film and conductive seed layers laminated on both surfaces of the base film, and has a substantially uniform thickness. Also, the plating device 1 for printed interconnect boards is a vertical continuous transfer type plating device that continuously and horizontally transfers the plurality of base boards X for printed interconnect boards while maintaining them in a generally vertical position. The plating device 1 for printed interconnect boards includes the pair of anodes 4 formed in a plate shape and disposed substantially parallel in the plating bath 2, and performs electrolytic plating while moving the rectangular base boards X for printed interconnect boards in the direction of arrow in the figures at the middle of the pair of anodes 4. Note that in FIG. 1 to FIG. 4, an external configuration other than the plating bath 2 in the plating device 1 for printed interconnect boards is omitted.

### Plating Bath

The plating bath 2 is a container whose longitudinal direction is the transferring direction of the base boards X for printed interconnect boards and having side and bottom surfaces that are in continuous in the longitudinal direction. In the plating bath 2, the plating solution Y is stored by an amount sufficient to immerse the base boards X for printed interconnect boards and the anodes 4. Examples of the plating solution Y include, but are not particularly limited to as long as electrolytic plating is possible, a plating solution containing copper, such as copper sulfate or copper pyrophosphate, a plating solution containing nickel or silver, and the like.

### Metal Jigs

The metal jigs 3 include frames 7 that are disposed on outer peripheries of the rectangular base boards X for printed interconnect boards and sandwich the base boards X for printed interconnect boards at the outer peripheries; and arms 8 that are connected to upper portions of the frames 7 and hold the base boards X for printed interconnect boards in a substantially vertical orientation. The frames 7 are ring-shaped rectangular frames that are detachably attached to pairs of side edge portions Xa, upper edge portions, and lower edge portions of the base boards X for printed interconnect boards, and have openings that expose front and back central surfaces of the base boards X for printed interconnect boards. The arms 8 are supporting devices that support the frames 7 in a suspended state with respect to a transferring mechanism (not illustrated) and transmit a force, received from the transferring mechanism in the transferring direction, to the frames 7. Also, while sequentially transferring the plurality of base boards X for printed interconnect boards in a substantially vertical orientation, the transferring mechanism supporting the arms 8 maintain an equal interval between the plurality of base boards X for printed interconnect boards. Therefore, by being attached to the base boards X for printed interconnect boards, the plurality of metal jigs 3 fix the base boards X for printed interconnect boards such that the side edge portions Xa of the plurality of base boards X for printed interconnect boards are parallel.

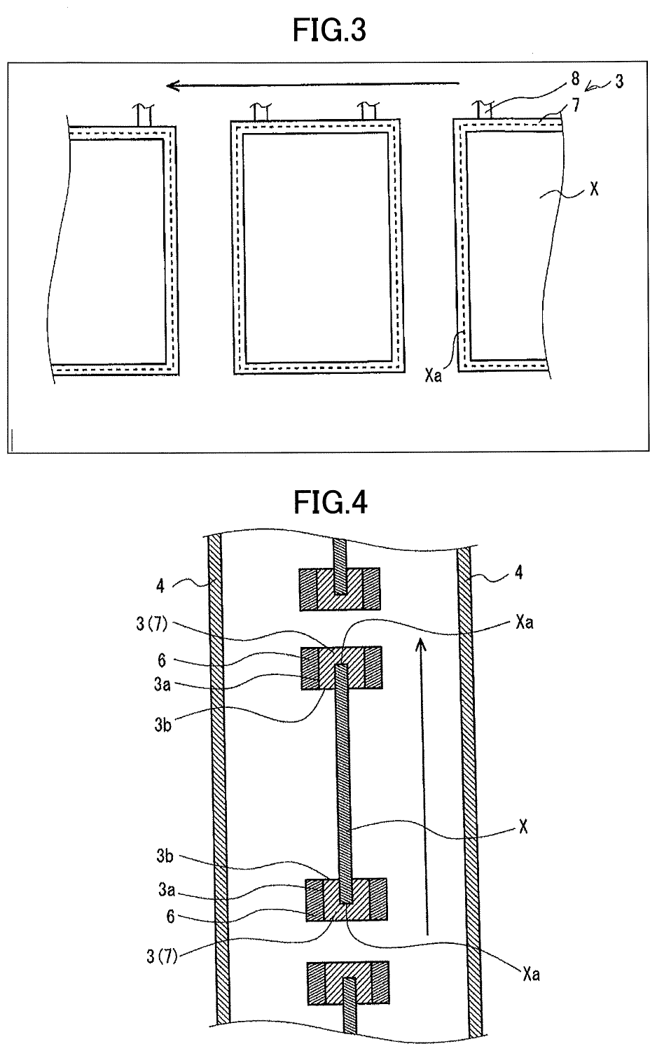

As illustrated in FIG. 3 and FIG. 4, at the time of being attached to the base boards X for printed interconnect boards, the frames 7 of the metal jigs 3 sandwich the side edge portions Xa from the front and back of the base boards X for printed interconnect boards and electrically connect the front and back surfaces of the base boards X for printed interconnect boards and the arms 8. As will be described later, because the negative electrode of the power supply of the voltage applying mechanism 5 is connected to the aims 8, the seed layers on the front surfaces of the base boards X for printed interconnect boards constitute a cathode at the time of plating. Although it is not particularly limited as long as it is electrically conductive, as a material of the frames 7 and the arms 8, stainless steel or copper is used, for example. Also, the frames 7 of the metal jigs 3 include shielding plates 6 on each of the two facing surfaces 3a, which are areas that face the anodes 4 at the time of electrolytic plating, and include exposed surfaces 3b, toward the center surfaces of the base boards X for printed interconnect boards and at areas from the base boards X for printed interconnect boards to the shielding plates 6, that are orthogonal to the base boards X for printed interconnect boards. The frames 7 are generally and substantially uniform in frame edge width and are generally and substantially uniform in frame edge thickness. The cross-sectional shape of the frames 7 is not particularly limited, but is preferably a cross-sectional shape that is substantially front-and-back-symmetrical with respect to the base boards X for printed interconnect boards, for example, can be a U-shape.

### Shielding Plates

The shielding plates 6 are insulating members that suppress deposition of plating on the metal jigs 3. Examples of the material of the shielding plates 6 include, but are not particularly limited to, polyvinyl chloride, polytetrafluoroethylene, polypropylene, polyetheretherketone, and the like. The shielding plates 6 are plate-shaped members that are formed in the same shape as the facing surfaces 3a and have a substantially uniform thickness, and are closely fixed to the facing surfaces 3a by resin bolts or the like. Note that the shielding plates 6 are not provided at areas other than the facing surfaces 3a of the frames 7, in order to provide a function of allowing an electric current to escape to surfaces not facing the anodes 4.

The inventors of the present invention have earnestly studied parameters to be able to control the plating thickness distribution in the plating device 1 for printed interconnect boards. As a result, the inventors of the present invention have found that, by properly adjusting the average width t of the exposed surfaces 3b between the base boards X for printed interconnect boards and the shielding plates 6 and the average distance a between the exposed surfaces 6 of the plurality of metal jigs 3 that are present between the base boards X for printed interconnect boards next to each other, the plating thickness on the surfaces of the base boards X for printed interconnect boards near the metal jigs 3 can be controlled. Then, the inventors of the present invention have found that, in the plating device 1 for printed interconnect boards, by adjusting the ratio of the average width t and the average distance a within an appropriate range, the plating thickness distribution applied to the base boars X for printed interconnect boards is controlled to be substantially uniform.

As the lower limit of the average width t/the average distance a, 3/44 is preferable, 1/11 is more preferable, and 1/9 is further more preferable. As the upper limit of the average width t/the average distance a, 9/44 is preferable, 2/11 is more preferable, ⅙ is more preferable, and 7/44 is further more preferable. When the average width t/the average distance a is less than the lower limit described above, there is a possibility that the plating thickness on the surfaces of the base boards X for printed interconnect boards near the metal jigs 3 becomes thick and the plating thickness distribution applied to the base boards X for printed interconnect boards becomes uneven. When the average width t/average distance a exceeds the upper limit described above, there is a possibility that the plating thickness on the surfaces of the base boards X for printed interconnect boards near the metal jigs 3 becomes thin and the plating thickness distribution applied to the base boards X for printed interconnect boards becomes uneven.

For example, in a case where the above described average distance a is approximately 22 mm, as the lower limit of the average width t of the exposed surfaces 3b between the base boards X for printed interconnect boards and the shielding plates 6, 1.5 mm is preferable, 2.0 mm is more preferable, and 2.4 mm is further more preferable. As the upper limit of the average width t, 4.5 mm is preferable, 4 mm is more preferable, 3.7 mm is more preferable, and 3.5 mm is further more preferable. When the average width t is less than the lower limit described above, there is a possibility that the function of allowing an electric current to escape to the exposed surfaces 3b becomes insufficient and the plating thickness on the surfaces of the base boards X for printed interconnect boards near the metal jigs 3 becomes thick. When the average width t exceeds the upper limit described above, there is a possibility that an electric current flowing to the exposed surfaces 3b excessively increases and the plating thickness on the surfaces of the base boards X for printed interconnect boards near the metal jigs 3 becomes thin.

### Anodes

The anodes 4 are flat plates whose longitudinal direction is the transferring direction of the base boards X for printed interconnect boards and that are continuous in the longitudinal direction. The anodes 4 are provided in the plating bath 2 so that and the short direction substantially matches the vertical direction. The printed device 1 for printed interconnect boards includes the pair of anodes 4 in the plating bath 2, and the two anodes 4 are arranged via an interval such that the plate surfaces are substantially parallel and face each other. Examples of the anodes 4 include, but are not particularly limited, a soluble anode composed mainly of a metal such as copper, nickel, or silver and an insoluble anode coated with platinum, iridium, or the like on a surface of a substrate such as titanium or niobium. Note that it is preferable to use an insoluble anode as the anodes 4 because it is easier to adjust the amount of electric current flowing to the surfaces of base boards for printed interconnect boards when the shape of the anodes 4 does not change.

### Voltage Applying Mechanism

The voltage applying mechanism 5 is a mechanism that applies a voltage from the base boards X for printed interconnect boards to the two anodes 4, and includes a power supply for applying the voltage. In the voltage applying mechanism 5, the negative electrode of the power supply is electrically connected via the arms 8 and the frames 7 to the base boards X for printed interconnect boards, and the positive electrode of the power supply is electrically connected to the two anodes 4.

### Advantages

The plating device 1 for printed interconnect boards includes the plurality of metal jigs 3 that are disposed on the pairs of side edge portions Xa of the base boards X for printed interconnect boards that constitute a cathode, and these metal jigs 3 fix the plurality of base boards X for printed interconnect boards such that the side edge portions Xa are parallel. Therefore, it is possible to continuously plate the plurality of base boards X for printed interconnect boards. Because the plurality of metal jigs 3 include the insulating shielding plates 6 on the facing surfaces 3a facing the anodes 4, a flow of an electric current to the facing surfaces 3a is suppressed. On the other hand, because the plurality of metal jigs 3 include, on sides of the base boards X for printed interconnect boards and between the base boards X for printed interconnect boards and the shielding plates 6, the exposed surfaces 3b that are orthogonal to the base boards X for printed interconnect boards, a flow of an electric current to the exposed surfaces 3b is permitted. Because the plurality of metal jigs 3 of the plating device 1 for printed interconnect boards include the shielding plates 6 and the exposed surfaces 3b described above, it is possible to adjust an amount of electric current that flows to the surfaces of the base boards X for printed interconnect boards near the metal jigs 3. Then, in the plating device 1 for printed interconnect boards, because the ratio of the average width t of the exposed surfaces 3b between the base boards X for printed interconnect boards and the shielding plates 6 and the average distance a between the exposed surfaces 6 of the plurality of metal jigs 3 that are present between the base boards X for printed interconnect boards next to each other is adjusted in an appropriate range, the amount of electric current that flows to the entire surfaces of the base boards X for printed interconnect boards is made uniform. As a result, the plating thickness distribution applied to the base boards X for printed interconnect boards is made uniform.

### Other Embodiments

It is to be understood that the embodiment disclosed herein is an example and are not restrictive in all respects. The scope of the present invention is not limited to the configuration of the above described embodiment, but is indicated by claims and is intended to include all changes within the meaning and scope of equivalence with the claims.

Although the metal jigs 3 include the frames 7 that are disposed on outer peripheries of the rectangular base boards X for printed interconnect boards and sandwich the base boards X for printed interconnect boards at the outer peripheries; and the arms 8 that are connected to upper portions of the frames 7 and hold the base boards X for printed interconnect boards in a substantially vertical orientation in the embodiment described above, the metal jigs 3 are not limited to the configuration described above as long as at least they are disposed on the pairs of side edge portions Xa of the base boards X for printed interconnect boards and can hold the base boards X for printed interconnect boards in a substantially vertical orientation.

Although plating is applied to base boards X for printed interconnect boards each including seed layers on both surfaces of a base film in the embodiment described above, base boards for printed interconnect boards to be used to be plated are not limited to including seed layers on both surfaces of a seed layer but may include a seed layer only on one surface.

### EXAMPLES

In the following, although the present invention will be specifically described with reference to examples, the present invention is not limited to the following examples.

A simulation was conducted with respect to a model of a plating device 1 for printed interconnect boards as described above using base boards for printed interconnect boards having an average thickness of 25 μm and metal jigs made of stainless steel. The average distance a between exposed surfaces of the plurality of metal jigs between the base boards for printed interconnect boards that are next to each other was set to be 22 mm, and the average width of the metal jigs in the transferring direction was set to be 7 mm. Note that the following evaluation was conducted by two-dimensional simulation in order to reduce the calculation amounts.

### Evaluation of FILM Thickness by Shielding Plate

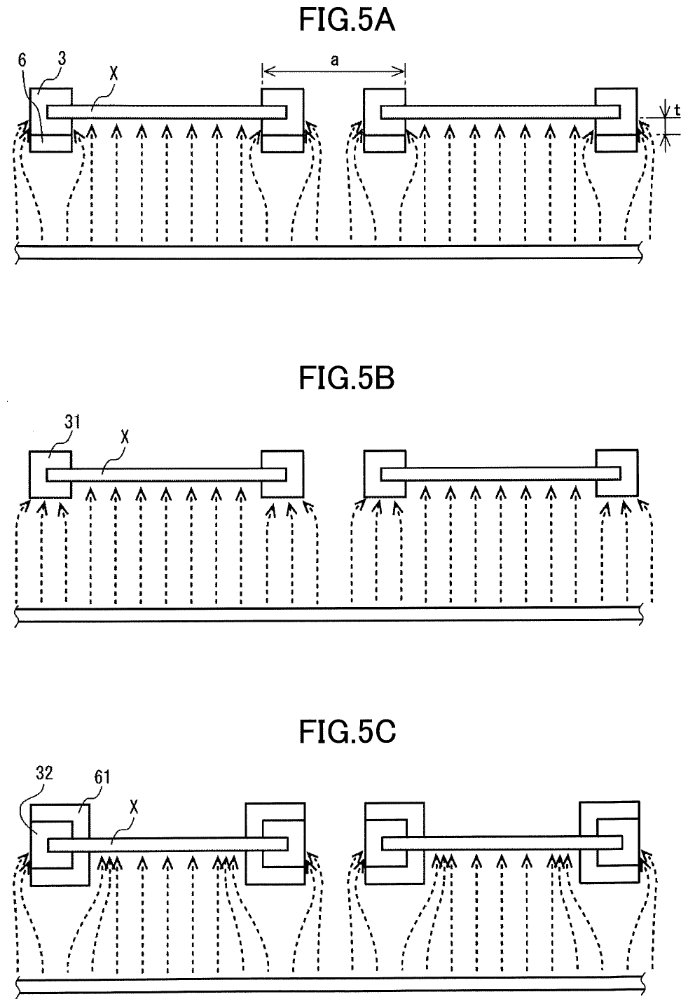

First, with respect to Example in which the average width t of the exposed surfaces from the base boards for printed interconnect boards to the facing surfaces that face the anode was 3 mm and the metal jigs 3 including the shielding plates 6 having the same shape as the facing surfaces were used (FIG. 5A); Comparative Example 1 in which metal jigs 31 without shielding plates were used (FIG. 5B); and Comparative Example 2 in which metal jigs 32 including shielding plates 61 on the facing surfaces and the entire side surfaces on the sides of the base boards for printed interconnect boards were used (FIG. 5C), directions in which electric current flow were calculated. Note that in FIGS. 5A to 5C, in order to qualitatively represent calculation results, the current directions from one anode to the base boards for printed interconnect boards are hypothetically indicated by broken lines with arrows.

In Example using the metal jigs 3, it was confirmed that the amount of electric current flowing to the surfaces of the base boards X for printed interconnect boards near the metal jigs 3 was adjusted to be equal to the amount of electric current flowing to the surfaces of the base boards X for printed interconnect boards away from the metal jigs 3, and the amount of electric current flowing to the entire surfaces of the base boards X for printed interconnect boards was substantially uniform.

On the other hand, in Comparative Example 1 using the metal jigs 31, it was confirmed that the amount of electric current flowing to the metal jigs 31 increased and the amount of electric current flowing to the surfaces of the base boards X for printed interconnect boards near the metal jigs 31 decreased. Conversely, in Comparative Example 2 using the metal jigs 32, it was confirmed that the amount of electric current flowing to the surfaces of the base boards X for printed interconnect boards near the metal jigs 32 increased because the shielding plates 61 covering the metal jigs 32 cut off the electric current. That is, in Comparative Example 1 or Comparative Example 2, it was confirmed that the amount of electric current flowing to the surfaces of the base boards X for printed interconnect boards near the metal jigs differed from the amount of electric current flowing to the surfaces of the base boards X for printed interconnect boards away from the metal jigs, and the amount of electric current flowing to the entire surfaces of the base boards X for printed interconnect boards was non-uniform.

### Evaluation of FILM Thickness by Average Width t of Exposed Surfaces

Next, using metal jigs 3 including shielding plates 6 having the same shape as the facing surfaces and setting the average widths t of the exposed surfaces 3b from the base boards X for printed interconnect boards to the facing surfaces 3a that face an anode to be 1 mm, 3 mm, and 5 mm, respectively, average film thicknesses at positions of 8 mm from the metal jigs 3 on the surfaces of the base boards X for printed interconnect boards (hereinafter, referred to as the end part average film thicknesses) and average film thicknesses at the centers of the surfaces of the base boards X for printed interconnect boards (hereinafter, referred to as the central average film thicknesses) were calculated.

In the example in which the average width t was set to be 3 mm, when the central average film thickness was 33.4 μm, the end part average film thickness was 32.5 pm. In this example, because the difference between the central average film thickness and the end part average film thickness was 0.9 μm, it can be said that the average film thickness at the entire surfaces of the base boards X for printed interconnect boards is substantially uniform.

In the example in which the average width t was set to be 1 mm, when the central average film thickness was 33.2 μm, the end part average film thickness was 34.9 μm. In this example, because the difference between the central average film thickness and the end part average film thickness was −1.7 pm, it can be said that the end part average film thickness was thicker than the central average film thickness.

In the example in which the average width t was set to be 5 mm, when the central average film thickness was 33.1 μm, the end part average film thickness was 30.8 μm. In this example, because the difference between the central average film thickness and the end part average film thickness was 2.3 μm, it can be said that the end part average film thickness was thinner than the central average film thickness.

### DESCRIPTION OF THE REFERENCE NUMERALS

1 plating device for printed interconnect boards

2 plating bath

3, 31, 32 metal jig

3a facing surface

3b exposed surface

4 anode

5 voltage applying mechanism

6, 61 shielding plate

7 frame

8 arm

X base boards for printed interconnect boards

Xa side edge portion

Y plating solution

1. A plating device for printed interconnect boards, the plating device comprising:
a plating bath configured to store a plating solution;
a plurality of metal jigs that are arranged in the plating bath and disposed on pairs of side edge portions of a plurality of base boards for printed interconnect boards that constitute a cathode to fix the base boards for printed interconnect boards such that the side edge portions are parallel;
an anode that is arranged in the plating bath and disposed to face the base boards for printed interconnect boards; and
a mechanism configured to apply a voltage to the anode and to the base boards for printed interconnect boards,
wherein the plurality of metal jigs include insulating shielding plates at areas facing the anode and include, on sides of the base boards for printed interconnect boards and between the base boards for printed interconnect boards and the shielding plates, exposed surfaces that are orthogonal to the base boards for printed interconnect boards.

2. The plating device for printed interconnect boards according to claim 1, wherein a plating thickness distribution is controlled based on an average width of the exposed surfaces between the base boards for printed interconnect boards and the shielding plates and an average distance between the exposed surfaces of the plurality of metal jigs that are present between the base boards for printed interconnect boards next to each other.

3. A metal jig to be used in a plating device for printed interconnect boards that includes:
a plating bath configured to store a plating solution;
a plurality of metal jigs that are arranged in the plating bath and disposed on pairs of side edge portions of a plurality of base boards for printed interconnect boards that constitute a cathode to fix the base boards for printed interconnect boards such that the side edge portions are parallel;
an anode that is arranged in the plating bath and disposed to face the base boards for printed interconnect boards; and
a mechanism configured to apply a voltage to the anode and to the base boards for printed interconnect boards,
wherein the metal jig includes insulating shielding plates at areas facing the anode and includes, on sides of one of the base boards for printed interconnect boards and between the one of the base boards for printed interconnect boards and the shielding plates, exposed surfaces that are orthogonal to the one of the base boards for printed interconnect boards.
